(19) United States
(12) Patent Application Publication
(10) Pub. No.: US 2026/0344356 A1
(43) Pub. Date: Oct. 29, 2026

(54) METHOD FOR MANUFACTURING A STRUCTURE FOR TRANSFERRING CHIPS

(71) Applicant: COMMISSARIAT A L'ENERGIE ATOMIQUE ET AUX ENERGIES ALTERNATIVES, Paris (FR)

(72) Inventors: Clément CASTAN, Grenoble Cedex 09 (FR); Jérôme DECHAMP, Grenoble Cedex 09 (FR); Laurent BALLY, Grenoble Cedex 09 (FR); Loic SANCHEZ, Grenoble Cedex 09 (FR); Frank FOURNEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/107,882

(22) PCT Filed: Sep. 5, 2023
(86) PCT No.: PCT/FR2023/051336

§ 371 Date: Feb. 28, 2025

(30) Foreign Application Priority Data
Sep. 6, 2022 (FR) 2208892

(51) Int. Cl. H10P 72/70; H10P 52/00

(52) U.S. Cl. CPC H10P 72/7432; H10P 52/00; H10P 72/7416; H10P 72/7428

(57) ABSTRACT

A method for manufacturing a transfer structure, comprising providing an intermediate substrate, bonding chips to a first surface of an intermediate substrate, whereby an array of chips is formed, the chips covering both a central zone and a peripheral zone of the intermediate substrate, the chips being positioned on a peripheral zone protruding from the surface of the intermediate substrate. The method also includes trimming, during which an end of the chips protruding from the surface of the intermediate substrate is removed, whereby the chips of the peripheral zone are truncated, and a transfer structure is obtained comprising the intermediate substrate covered by a pseudo-donor substrate formed by an array of chips the array of the chips being offset from a crystallographic plane of the intermediate substrate.

### TECHNICAL FIELD

The present invention relates to the general field of methods for transferring material from a donor substrate to a receptor substrate, and more particularly to methods for transferring a pseudo substrate formed by an array of chips to a receptor substrate.

The invention relates to a method for manufacturing a structure enabling the transfer of a pseudo substrate formed by an array of chips to a receptor substrate.

The invention also relates to a transfer structure of this kind.

The invention also relates to a transfer method using a structure of this kind.

The invention has applications in many fields of industry, particularly for the manufacture of substrates from a material of interest that only exists in smaller sizes. The invention is particularly advantageous for manufacturing substrates of semiconductor material, for example type III-V, and in particular indium phosphide (InP) substrates.

The invention is particularly useful because it makes it possible to manufacture a transfer structure, comprising a pseudo substrate formed by an array of chips, that is mechanically stable and less fragile than that of the prior art.

### PRIOR ART

The semiconductor materials GaAs and InP are promising materials for numerous applications such as photonics and optoelectronics. However, these materials are very fragile, rare and expensive. They are therefore generally manufactured in the form of small-diameter ingots (typically with a diameter of 100 mm or a diameter up to 150 mm), which limits the scope of their applications.

In order to overcome this drawback, as described in the article by Ghyselen et al. (Phys. Status Solidi A 2022, 219, 2100543), InPOSi substrates with a diameter of 200 mm can be manufactured by producing an array of InP chips forming a pseudo substrate, then transferring a thin layer of this pseudo substrate onto an SOI substrate. The method comprises the following steps:
bonding the chips to an intermediate substrate (typically a wafer of semi-conductor material, for example silicon), whereby a transfer structure is obtained comprising an intermediate substrate covered by an array of chips, the array of chips forming a pseudo-donor substrate made of material of interest (InP),
carrying out a Smart Cut™ process to transfer a thin layer of the pseudo-donor substrate to a receptor substrate.

At the end of this process, it is possible to reuse the pseudo-donor substrate to re-transfer a thin layer of material of interest to another receptor substrate.

In general, as shown in FIG. 1, the chips have a square shape and the substrate has a circular shape. No chip can therefore be bonded to the edge of the substrate (FIG. 1). The chip-free zone, known as the exclusion zone, has a crenellated shape. The substrates can thus be transported in standard micro-electronic boxes.

However, the presence of the chips bonded to the substrate leads to a fragility of the substrate, this fragility being exacerbated by the cleavage along the space between the chips (inter-chip space) and impairing many surface treatment processes, such as chemical mechanical polishing (CMP).

There is therefore a need to manufacture less fragile transfer structures.

### DESCRIPTION OF THE INVENTION

One aim of the present invention is to overcome the drawbacks of the prior art and to propose a method for manufacturing a structure for transferring chips that overcomes the drawbacks of the prior art and, in particular, has improved mechanical strength.

For this, the present invention proposes a method for manufacturing a chip transfer structure, comprising the following steps:
i) providing an intermediate substrate, having a first surface,
ii) bonding chips to the first surface of the intermediate substrate, whereby an array of chips is formed, the chips covering both the central zone and the peripheral zone of the first surface of the intermediate substrate, the chips covering the peripheral zone protruding from the first surface of the intermediate substrate,
the method also comprising a step iii) of trimming, after step ii), during which the end of the chips protruding from the first surface of the intermediate substrate is removed, whereby the chips of the peripheral part are truncated, and a chip transfer structure is obtained comprising an intermediate substrate covered by a pseudo-donor substrate formed by an array of chips.

The invention differs fundamentally from the prior art in that the intermediate substrate is covered by an array of chips both in the central zone of the first surface and in the peripheral zone of the first surface. This results in a wafer array forming a pseudo substrate that can be transferred to a receptor substrate.

The chip pattern (i.e. the array of chips) formed by all the chips is circular, like the first surface of the intermediate substrate. This provides a pseudo substrate with a standard microelectronics shape.

The chips do not protrude from the intermediate substrate and the structure can be easily transported in conventional boxes, handled and used in microelectronics equipment.

The round shape also makes it easier to dry the plates using the Marangoni effect or centrifugation, facilitating all the wet processing steps that take place with rotating substrates.

Moreover, bonding chips to all the intermediate substrate and subsequently trimming it maximizes the surface area of the transferred layer and therefore increases the efficiency of the method. For example, CMP steps tend to round off the edge of extreme edge chips. The rounded edges will be the edges of the truncated chips here. Entire chips in the central zone will thus be preserved.

The absence of the crenellated edges of the array of chips at the edge of the pattern will reduce wear and tear on consumables, particularly in processes such as chemical mechanical polishing (CMP).

Moreover, the mechanical strength of the resulting structure is improved compared with the substrates from the prior art.

Advantageously, step iii) of trimming is carried out by trimming and/or grinding.

Advantageously, after step ii), the method comprises a step iv) during which the chips are slimmed down. Step iii) is, advantageously, carried out after step iv). It could also be carried out between step ii) and step iii).

Advantageously, the chips are bonded to the intermediate substrate by direct bonding.

According to one particularly advantageous embodiment, the array of the chips is offset from the crystallographic plane of the substrate. In other words, the cutting lines formed by the inter-chip spaces are rotated with respect to the crystallographic plane of the substrate to which they are bonded, which limits cleavages and therefore the breakage of the structure. The resulting structures are thus less fragile, which makes them easier to handle and use in automated equipment.

This misalignment is in no way problematic for the final application because, when the chips will be transferred, it will be possible to realign the crystal planes of the material of interest on the final substrate.

The chips, for example, are made of a semiconductor material, in particular a III-V semiconductor material, such as indium phosphide.

Advantageously, the chips covering the peripheral zone are different from the chips covering the central zone, for example having different qualities, different materials and/or different dimensions.

The invention also relates to a chip transfer structure comprising an intermediate substrate covered by a pseudo-donor substrate formed by an array of chips, the chips being bonded to a first surface of the intermediate substrate, the chips covering both the central zone and the peripheral zone of the first surface of the intermediate substrate. The chips positioned on the peripheral part are truncated so as to not protrude from the first surface of the intermediate substrate.

Advantageously, there can be two populations of chips: the “central” chips and the edge chips. These two populations can have different qualities (for example, the doping level or the crystallographic defect rate). They can also be of different types to minimize manufacturing costs.

Advantageously, the array of the chips is offset from the crystallographic plane of the substrate.

Advantageously, the intermediate substrate is made of silicon and/or the chips are made of InP.

The invention also relates to a method for transferring chips comprising the following steps:
a) providing a transfer structure as defined above, comprising an intermediate substrate covered by a pseudo-donor substrate formed by an array of chips, the chips being bonded to a first surface of the intermediate substrate, the chips covering both the central zone and the peripheral zone of the first surface of the intermediate substrate, the chips positioned on the peripheral part being truncated so as to not protrude from the first surface of the intermediate substrate.
b) transferring a layer of the pseudo substrate to a receptor substrate, for example with a Smart Cut™ process.

Other features and advantages of the invention will become apparent from the following additional description.

It goes without saying that this additional description is given only as an illustration of the object of the invention and should in no way be interpreted as a limitation of this object.

### BRIEF DESCRIPTION OF THE DRAWINGS

The present invention will be better understood upon reading the description of exemplary embodiments given for information purposes only and in no way limiting with reference to the appended drawings wherein:

FIG. 1 described above in the prior art, schematically shows, in plan view, an intermediate substrate covered by chips to be transferred.

FIGS. 2A and 2B schematically show various steps of a method for manufacturing a chip transfer structure, comprising an intermediate substrate covered by chips to be transferred, according to a first embodiment of the invention, the transfer structure being shown in plan view.

FIGS. 3A and 3B schematically show various steps of a method for manufacturing a chip transfer structure, comprising an intermediate substrate covered by chips to be transferred, according to a second embodiment of the invention, the transfer structure being shown in plan view.

FIGS. 4A, 4B, 4C, 4D and 4E schematically show various steps of a method for manufacturing a chip transfer structure, comprising an intermediate substrate covered by chips to be transferred, according to a third embodiment of the invention, the transfer structure being shown in plan view.

FIG. 5 shows a schematic cross-section of the transfer structure shown in FIG. 4E.

FIG. 6A is a photographic image of a chip transfer structure, in which the array of chips is aligned with respect to the notch according to a particular embodiment of the invention, the structure being made of silicon.

FIG. 6B is a photographic image of a chip transfer structure, in which the array of chips is misaligned with respect to the notch by an angle of 7° according to a particular embodiment of the invention, the structure being made of silicon.

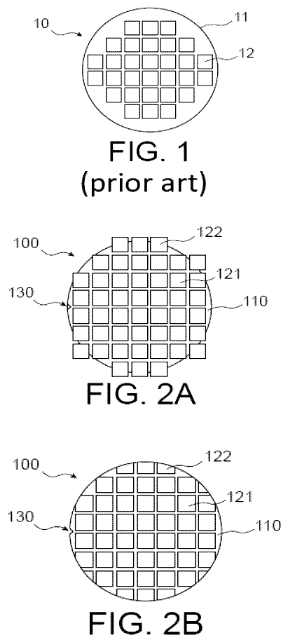

The different portions shown in the figures are not necessarily plotted according to a uniform scale, to make the figures more readable.

The various possibilities (alternatives and embodiments) must be understood as not being mutually exclusive and can be combined with one another.

Furthermore, in the description hereinafter, terms that depend on the orientation, such as “top”, “bottom”, etc., of a structure apply while considering that the structure is oriented as illustrated in the figures.

### DETAILED DISCLOSURE OF PARTICULAR EMBODIMENTS

We are now going to describe in more detail the method for manufacturing a structure 100 used for transferring a pseudo substrate formed by an array of chips 121, 122 made of material of interest.

The invention is particularly useful for manufacturing large-diameter substrates (typically 200 mm or 300 mm in diameter), and in particular for manufacturing large-diameter InPOSi substrates. However, the application is not limited to InP and is applicable to many other materials.

As shown in FIG. 2A-2B, 3A-3B or 4D-4E, the method for manufacturing the transfer structure 100 comprises the following successive steps:
i) providing an intermediate substrate 110,
ii) bonding chips 121, 122 to a first surface of the intermediate substrate, a first group of chips 121 covering the central zone of the first surface of the intermediate substrate 110 and a second group of chips 122 covering the peripheral zone of the first surface of the intermediate substrate 110 and protruding from the first surface of the intermediate substrate 110 (FIGS. 2A, 3A, 4D),
iii) carrying out a trimming step so as to remove the end of the chips 122 protruding from the first surface of the intermediate substrate 110, whereby the chips 122 of the peripheral zone are truncated, and a transfer structure 100 is obtained comprising an intermediate substrate (110) covered by a pseudo-donor substrate formed by an array of chips (121, 122), the array having the same shape as the intermediate substrate 110 (FIGS. 2B, 3B, 4E).

The method can also comprise a step iv) during which the chips 121, 122 are slimmed down. Step iv) can be carried out either between step ii) and step iii) or after step iii). It is preferably carried out after step iii).

The intermediate substrate 110 provided in step i) is preferably made of a semiconductor material. It is, for example, made of silicon. For example, an intermediate silicon substrate 110 with a crystalline orientation 100 or 111 is chosen. It could also be made of germanium. According to another embodiment, the substrate is made of fused silica (or glass).

The intermediate substrate 110 is a circular plate or wafer. It can, for example, be a plate with a diameter of 200 mm or 300 mm.

The intermediate substrate 110 comprises a first surface (or first main surface) to which the chips 121, 122 are going to be fixed and a second surface (or second main surface). The first surface and the second surface are parallel to each other. They are separated by a thickness, for example between 100 and 2000 μm and more specifically between 500 μm and 800 μm.

The intermediate substrate 110 has, on its periphery, a notch 130 for identification. It is used to identify the orientation of the plate during the various steps of the process. This notch 130 is generally semi-circular. It can, for example, penetrate the intermediate substrate 110 by several millimetres (for example 1 mm). The size of the notches is defined in the SEMI Standards.

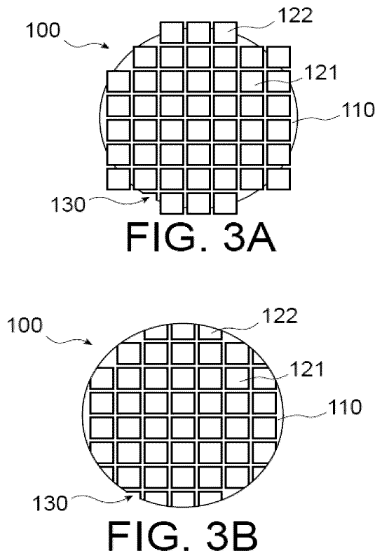

During step ii), the chips 121, 122 are fixed to the intermediate substrate 110 (FIG. 2A or FIG. 3A).

A first group of chips 121 is positioned on the central zone of the first surface of the intermediate substrate 110. The chips 121 of the first group of chips do not protrude from the first surface of the intermediate substrate 110.

A second group of chips 122 is positioned on the peripheral zone of the first surface of the intermediate substrate 110. The chips 122 of the second group of chips protrude from the first surface of the intermediate substrate 110.

The bonded chips 121, 122 can be identical or different. They can be made of different materials. For example, the chips 121 of the central zone can be made of a first material and the chips 122 of the peripheral zone can be made of a second material. In particular, it will be advantageous to choose inexpensive chips 122 for the peripheral zone as these chips 122 will be truncated during step iii).

One or more of the following materials are chosen: InP, AsGa, silicon, germanium, LaNiO₃ (LNO), lithium titanate (LTO), SiC, diamond, sapphire, silica and glass.

The chips 121, 122 can have integration such as epitaxial layers, metallic interconnect levels and/or CMOS.

It is possible to integrate chips 121, 122 with different functions made from different materials on the same intermediate substrate 110.

The chips 121, 122 can have identical or different surfaces and/or identical or different shapes. For example, the chips 121 of the central zone can have a larger surface than the surface of the chips 122 of the peripheral zone in order to optimize surface filling. It is advantageous to avoid losing too much material during step iii).

The chips 121, 122 can be of any shape. They can, for example, be square or rectangular. They are preferably square. For example, the chips have surfaces between 0.1 mm*0.1 mm and 20*20 mm and, preferably, between 1 mm*1 mm to 10*10 mm. Here and hereinafter, between X and Y means that the limits are included. The chips 121, 122 are, for example, chips with a surface area of 1cm².

The thickness of the chips 121, 122 is preferably a few dozen to a few hundred micrometres, for example between 50 μm and 2000 μm and more specifically between 350 um and 775 μm.

The chips 121, 122 are advantageously evenly spaced apart. Very advantageously, their positioning enables cutting lines to be formed. Even more advantageously, the chips 121, 122 are arranged to form a cutting grid.

The space between the chips 121, 122, called the inter-chip space, is, for example, between 0.01 and 10 mm and more specifically between 0.2 and 1 mm.

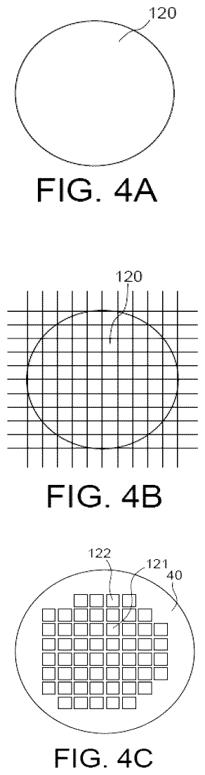

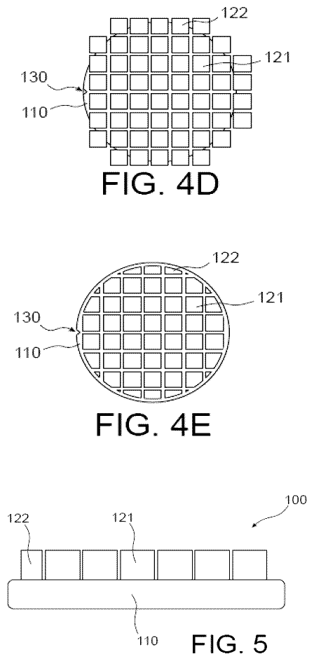

The bonding pattern of the chips 121, 122 can be aligned with the crystalline planes of the intermediate substrate 110 to which they are bonded. They are therefore aligned with the notch 130 (FIG. 2B, FIG. 4E). If we consider a line L passing through the notch and through the centre of the first circular surface of the substrate, the cutting lines are parallel or perpendicular to this line L.

According to one advantageous variant, the pattern of the chips 121, 122 is not aligned with the crystalline planes of the intermediate substrate 110 to which they are bonded (FIG. 3B). They are therefore misaligned with the notch 130. In other words, the cutting lines are neither parallel nor perpendicular to the line L defined above. This misalignment limits the cleavages and reduces the fragility of the final structure. Advantageously, in order to enhance this effect, the crystallographic planes of the chips are not aligned with the crystallographic planes of the intermediate substrate either.

The chips 121, 122 can be bonded using different bonding techniques (direct bonding, polymer bonding, eutectic bonding, thermocompression bonding, anodic bonding).

The bonding is preferably direct bonding.

As shown in FIGS. 4A, 4B, 4C and 4D, step ii) can comprise the following sub-steps:
providing one or more substrates 120 to be cut, the substrates 120 may be of the same material or different materials and/or the substrates 120 may be of identical sizes or different sizes (a single substrate to be cut is shown is shown in FIG. 4A),
cutting the substrate(s) 120 along cutting lines (shown by the lines in FIG. 4B) so as to form chips,
positioning the chips 121, 122 on an adhesive backing 40 (FIG. 4C) manually or, preferably, automatically (with a pick and place machine),
bonding the chips 121, 122 to the intermediate substrate 110 (FIG. 4D).

By way of illustration and without limitation, the substrates to be cut can be circular InP substrates with a diameter of 50, 75 or 100 mm. For example, for an intermediate substrate 110 that is 200 mm or 300 mm, ten plates with a diameter of 100 mm can be cut.

A heat treatment can be advantageously carried out after bonding the chips 121, 122 to increase the adhesion energy between the chips 121, 122 and the intermediate substrate 110.

During step iii), the intermediate substrate 110 is trimmed in order to remove at least the end of the chips 122 that protrudes from the intermediate substrate 110.

According to one embodiment, only the piece that protrudes is removed, which leads to the formation of truncated chips 122. The chips 122 on the periphery of the intermediate substrate 110 thus partly match the shape of the substrate 110. The array of chips therefore has the same shape and same surface area as the first surface of the intermediate substrate 110 (FIGS. 2B and 3B).

According to another embodiment, it is possible to remove a little more material to clear the natural edge (‘bevel’) of the substrate 110 and thus facilitate the use of the structure in automatic machines set on the natural edges of the substrates 110. The array of chips therefore has the same shape as the first surface of the intermediate substrate 100 but a smaller surface area than the first surface of the intermediate substrate 110 (FIG. 4E).

Advantageously, at least the entire unbonded zone of the chips is removed. This area can be seen, for example, under an acoustic microscope.

The trimming step is advantageously carried out by mechanical means.

This step can be preferably carried out by grinding and/or trimming. Trimming will preferably be carried out initially, followed by grinding.

By using a protruding bond and implementing a trimming step, it is possible to obtain a transfer structure 100 whose periphery is circular and, in particular, whose pseudo substrate periphery is circular, like the intermediate substrate 110.

During step iv), the chips 121, 122 are slimmed down. The chips 121, 122 can be slimmed down by grinding and/or polished by chemical mechanical polishing (CMP). The CMP step gives the chips 121, 122 a mirror-polished appearance. After step iv), the chips 121, 122 have the same thickness. For example, the chips are slimmed down to have thicknesses or around 550 μm. It is also possible to go down to thicknesses of a few microns to a few dozen microns.

Advantageously, the remaining thickness is chosen so as to be able to make successive layer transfers with a single intermediate plate.

Advantageously, the chips are slimmed down by at least fifteen microns.

Step iv) can comprise the following sub-steps:
depositing a filling material between the chips 121, 122 (i.e. in the inter-chip space), the thickness between the chips is preferably greater than the final thickness of the chips after slimming down, the filling material can also cover the chips 121, 122 locally or completely (i.e. the chips 121, 122 are enclosed by the filling material),
slimming down the chips 121, 122,
carrying out a step of levelling the resulting mixed surface (chips 121, 122-filling material), for example, by chemical mechanical polishing, in order to obtain a flat surface, or a surface with the filling material slightly recessed, for example by a few nanometres to a few dozen nanometres

After the method of manufacturing the transfer structure 100, a structure 100 is obtained comprising an intermediate substrate 110 covered by an array of chips 121, 122 forming a pseudo substrate. There is no exclusion zone or a limited circular exclusion zone. The presence of a limited exclusion zone allows to keep the extreme edge of the plate (‘bevel’) free for robots to grip substrates.

Both the central zone and the peripheral zone of the intermediate substrate 110 are covered by chips 121, 122. The chips 121 of the central zone are whole. The chips 122 of the peripheral zone are truncated so as to not protrude from the surface of the intermediate substrate 110.

The array of chips 121, 122 has the same shape as the intermediate substrate 110 (FIGS. 2B, 3B, 4E, 5).

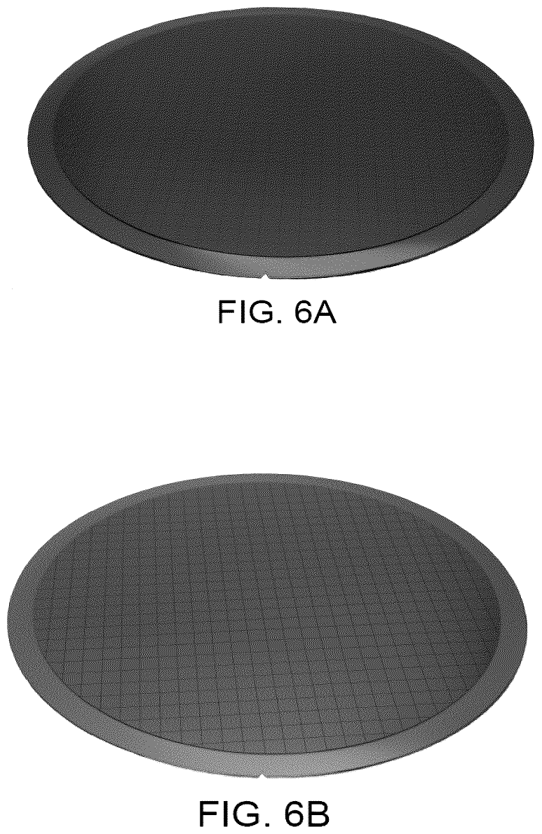

FIGS. 6A and 6B are photographic images, respectively, of an aligned transfer structure 100 (i.e. array of chips aligned with respect to the notch) and of a misaligned transfer structure 100 (i.e. array of chips misaligned with respect to the notch; angle of 7°).

The resulting structure 100 can be used to transfer the pseudo-donor substrate to a receptor substrate. The receptor substrate is preferably a wafer. The receptor substrate is preferably made of semiconductor material. For example, it can be an oxidized silicon substrate or an SOI (Silicon On Insulator) substrate, i.e. a substrate comprising a layer of silicon on a layer of insulator, typically a layer of SIO₂. The SOI substrate is generally also oxidized and therefore has an oxide layer on the surface.

The pseudo-donor substrate is preferably transferred to the receptor substrate with a Smart Cut™ process.

The Smart Cut™ process can comprise:
forming in the pseudo-donor substrate an embrittlement zone by implantation defining a thin layer intended to be transferred to the receptor substrate,
bonding the transfer structure (i.e. the intermediate substrate and the array of chips) to the receptor substrate, by direct bonding, the chips being in contact with the receptor substrate,
splitting the intermediate structure according to the embrittlement zone so as to transfer the thin layer of the pseudo-donor substrate to the receptor substrate.

The embrittlement zone is formed by implanting atomic species, such as hydrogen or helium. The conditions of implantation (dose, energy) will be determined by a person skilled in the art according to the nature of the substrate and the desired depth of implantation.

Surface treatments can be carried out on the pseudo substrate and on the receptor substrate prior to bonding to increase the bonding energy.

Splitting can be initiated, for example, by applying a mechanical force to the embrittlement zone or by heat treatment (annealing).

After the layer of interest has been transferred to the receptor substrate, the transfer structure 100 can be used again to perform a new transfer of the material of interest.

### Illustrative and Non-Limiting Examples of one Embodiment

### Trimming the Plates Intended to Form the Chips

The InP plate 120 to be trimmed is mounted on a first UV release adhesive film, which is stretched over a cutting ring. The chips 121, 122 are cut out of the plate using a diamond saw. After trimming, the surfaces of the chips are cleaned. To reconstruct the surface of a 300 mm wafer 110, it is necessary to cut around ten 100 mm diameter InP plates 120.

### Positioning the Chips on the Adhesive Film

The adhesive film is exposed to UV light to make it easier to grip the chips.

The chips 121, 122 are picked up and then positioned on a second blank UV release adhesive film 40 stretched over a cutting ring. This step can be carried out automatically with a “pick and place” machine. The aim is to reconstruct on this adhesive film 40 a plate that is larger than the donor plate (i.e. the intermediate substrate). The diameter of the reconstructed surface is advantageously greater than the diameter of the intermediate substrate 110 which will receive the chips 121, 122 in order to maximize the reconstructed surface after the chips 121, 122 have been trimmed.

### Cleaning and Bonding the Chips to the Intermediate Substrate

Once the surface has been reconstructed on the adhesive film 40, the chips 121, 122 are collectively cleaned in order to remove hydrocarbons and particles. By way of illustration, an initial UV/ozone cleaning can be carried out to remove hydrocarbons. The chips 121, 122 can then collectively undergo megasonic cleaning.

The chips 121, 122 are placed face down on the intermediate substrate 110. Slight pressure is applied to the back of the adhesive film 40 to facilitate the contact between the chips 121, 122 and the intermediate substrate 110. Once the chips 121, 122 have been bonded, the adhesive film 40 is exposed and peeled off. This structure with “protruding” chips 122 is advantageously subjected to heat treatment, for example annealing between 250 and 400 °C in order to reinforce the bonding interface.

### Trimming by Grinding

The intermediate substrate 110 covered with chips 121, 122, some of which protrude from its surface, can be trimmed by grinding.

For this purpose, the intermediate substrate 110 to which the chips 121, 122 are bonded is sucked onto a chuck.

The assembly is transferred under a grinding wheel so that the outer periphery of the wheel's teeth is positioned vertically at the required trimming width. Typically, to make the plates compatible with other microelectronics equipment, this width is reduced to a width greater than 1.5 mm in relation to the edge of the substrate 110. This frees up the natural edge of the plate 110 and its notch 130.

The wheel and/or the chuck, on which the intermediate substrate 110 is positioned, are then rotated and the wheel is lowered in parallel so as to remove the thickness of the chips bonded to the intermediate substrate 110.

The rotation speed (between 100 and 3000 rpm) and the wheel's descent speed (between 0.01 and 50 μm/s) are adapted depending on the materials and thicknesses to be removed. Several descent speeds can be combined during the step. The rotation speed of the chuck is also adapted (the speed being between 100 and 300 rpm).

### Trimming by Cutting

The intermediate substrate 110 covered with chips 121, 122, some of which protrude from its surface, can be trimmed using the abrasive circular blade cutting technique.

For this purpose, the intermediate substrate 110 to which the chips are bonded is held on a chuck.

The cutting blade is circular. It has an abrasive lining around its periphery, the height of which is at least equal to the working depth. This abrasive lining comprises a binder, abrasive grains such as diamond or corundum, the size of which is adapted to the material to be cut, and a controlled porosity.

The intermediate substrate 110 is centred thanks to an optical alignment module or a mechanical shim defined on the edges of the intermediate substrate.

The blade is rotated and descends to a defined height in relation to the chuck and the tangent point with the trimming diameter.

The intermediate substrate 110 performs a complete rotational movement, which constitutes a trimming operation.

Depending on the width of the blade and width of the trimming, several operations may be necessary in order to trim the plate.

The blade can also enter the intermediate substrate 110 via the edge of the plate, rather than vertically. In this case, the intermediate substrate 110 first performs a translational movement until it reaches the tangent point to the trimming and then the intermediate substrate performs a complete rotation.

Typically, to make the substrates compatible with other microelectronics equipment, this width is reduced to at least 1.5 mm, which corresponds to the trimming value of the notch 130.

### Slimming Down the Chips Positioned on the Trimmed Intermediate Substrate

The chips 121, 122 can be slimmed down by grinding. The intermediate substrate 110 is positioned on a chuck. The surface of the intermediate substrate 110 opposite the chips 121, 122 is in contact with the chuck.

The assembly is positioned under a grinding wheel. The wheel is vertical to the intermediate substrate 110. The wheel comprises a set of teeth arranged around the periphery of a metallic base containing synthetic diamond grains with sizes adapted to the material, a resin or other binder, and a controlled porosity.

The wheel and/or the chuck are then rotated and the wheel is lowered so as to slim down the chips bonded to the support substrate to the same thickness.

The rotation speed (between 100 and 3000 rpm) and the wheel's descent speed (between 0.01 and 50 μm/s) are adapted depending on the materials and thicknesses to be removed. Several descent speeds can be combined during this step. The rotation speed of the chuck can be between 100 and 300 rpm.

### Chemical Mechanical Polishing (CMP) on the Trimmed Intermediate Substrate

The intermediate substrate 110 covered by the array of chips 121, 122 can be subjected to a step of chemical mechanical polishing (CMP).

This CMP step is used to compensate for the roughness after grinding.

The intermediate substrate 110 is then subjected to a step of buffing, then of cleaning. The surface of the chips 121, 122 is thus compatible with direct bonding.

### Transferring the Chips to a Receptor Substrate

The resulting structure 100 can be used to transfer the chips 121, 122 to a receptor substrate or a final substrate.

The chips 121, 122 are transferred to the receptor substrate, for example, by implementing the steps of implantation, bonding and fracture.

A misaligned transfer structure (i.e. one where the array is offset from the crystallographic plane of the intermediate substrate 110) and an aligned structure (i.e. one where the array is aligned with the crystallographic plane of the intermediate substrate 110) have been manufactured.

1. Method A method for manufacturing a chip transfer structure the method comprising:
(i) providing an intermediate substrate having a first surface, and
(ii) bonding chips to the first surface of the intermediate substrate the chips covering both a central zone and a peripheral zone of the first surface of the intermediate substrate the chips covering the peripheral zone protruding from a surface of the intermediate substrate
wherein the method further comprises a step (iii) of trimming, after the step (ii), during which an end of the chips protruding from the first surface of the intermediate substrate is removed, whereby the chips of the peripheral zone are truncated, and a transfer structure is obtained comprising an intermediate substrate (110) covered by a pseudo-donor substrate formed by an array of chips (121, 122), and
wherein the array of the chips is offset from a crystallographic plane of the intermediate substrate

2. The method according to claim 1, wherein a the crystallographic plane of the chips is not aligned with the crystallographic plane of the intermediate substrate.

3. The method according to claim 1, wherein the step (iii) is carried out by trimming and/or grinding.

4. The method according to claim 1, wherein, after the step (ii), the method comprises a step (iv) during which the chips are slimmed down.

5. The method according to claim 4, wherein the step (iii) is carried out after the step (iv).

6. The method according to claim 1, wherein the chips are bonded to the intermediate substrate by direct bonding.

7. The method according to claim 1, wherein the chips covering the peripheral zone are different from the chips covering the central zone, having different qualities, different materials, and/or different dimensions.

8. A chip transfer structure, comprising:
an intermediate substrate covered by a pseudo-donor substrate formed by an array of chips, the chips being bonded to a first surface of the intermediate substrate,
wherein the chips cover both a central zone and a peripheral zone of a first surface of the intermediate substrate the chips positioned on the peripheral zone being truncated so as to not protrude from the first surface of the intermediate substrate and the array of the chips is offset from a crystallographic plane of the intermediate substrate.

9. The structure according to claim 8, wherein a crystallographic plane of the chips is not aligned with the crystallographic plane of the intermediate substrate.

10. The structure according to claim 8, wherein the intermediate substrate is made of silicon and the chips are made of InP.

11. A method for transferring chips, comprising:
providing a transfer structure as defined in claim 8, comprising the intermediate substrate covered by the pseudo-donor substrate formed by the array of chips, the chips being bonded to the first surface of the intermediate substrate the chips covering both the central zone and the peripheral zone of the first surface of the intermediate substrate the chips positioned on the peripheral zone being truncated so as to not protrude from the first surface of the intermediate substrate and the array of the chips being offset from the crystallographic plane of the intermediate substrate and
transferring a layer of the pseudo-donor substrate to a receptor substrate.

12. The method for transferring chips according to claim 11, wherein the crystallographic plane of the chips, is not aligned with the crystallographic plane of the intermediate substrate
